(19) United States
(12) Patent Application Publication
(10) Pub. No.: US 2008/0054364 A1
(43) Pub. Date: Mar. 6, 2008

(54) SEMICONDUCTOR DEVICE HAVING CMOS DEVICE

(76) Inventor: Akira HOKAZONO, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/847,865

(22) Filed: Aug. 30, 2007

(30) Foreign Application Priority Data
Aug. 31, 2006 (JP) 2006-236740

(51) Int. Cl. H01L 21/8238

(52) U.S. Cl. 257/369; 257/E21.632

(57) ABSTRACT

A semiconductor device includes an n-channel MIS transistor and a p-channel MIS transistor. The n-channel MIS transistor includes a first source region formed in a semiconductor region on a substrate, a first drain region formed in the semiconductor region apart from the first source region, a first gate insulating film, and a first gate electrode formed on the first gate insulating film. The p-channel MIS transistor includes a second source region formed in the semiconductor region, a second drain region formed in the semiconductor region apart from the second source region, a second gate insulating film, and a second gate electrode formed on the second gate insulating film. The first and second drain regions are arranged to be connected to each other and made of the same material, and one of the first and second source regions is made of a material different from the first and second drain regions.

### CROSS-REFERENCE TO RELATED APPLICATIONS

This application is based upon and claims the benefit of priority from prior Japanese Patent Application No. 2006-236740, filed Aug. 31, 2006, the entire contents of which are incorporated herein by reference.

### BACKGROUND OF THE INVENTION

1. Field of the Invention

The present invention relates to a semiconductor device having a CMOS device and, for example, to a CMOS structure in, e.g., a static random access memory (SRAM), inverter, or logic circuit.

2. Description of the Related Art

Recently, the following process is proposed by taking account of the application of strain to a channel in order to improve the transistor characteristics. Silicon carbide (SiC) is buried in n-channel MIS transistor to apply tensile stress to a channel region. Also, silicon germanium (SiGe) is buried in a p-channel MIS transistor to apply compressive stress to a channel region.

For example, Jpn. Pat. Appln. KOKAI Publication No. 2005-175495 describes a semiconductor structure in which SiC and SiGe islands are respectively formed in nFET and pFET channels, and an STI is formed between the NFET and pFET. When the use of an SOI (Silicon On Insulator) structure makes it unnecessary to take account of a junction leakage and substrate potential, a structure having no STI is sometimes formed in order to downsize a semiconductor device. A semiconductor device like this has a junction region where the SiC drain region of an n-channel MOS transistor (to be referred to as an nMOS transistor hereinafter) connects to the SiGe drain region of a p-channel MOS transistor (to be referred to as a pMOS transistor hereinafter). A crystal defect may occur in this junction region because materials having different interstitial distances come in contact with each other in the junction region. This crystal defect in the junction region has an adverse effect on the transistor characteristics of the nMOS transistor and pMOS transistor.

### BRIEF SUMMARY OF THE INVENTION

A semiconductor device according to the first aspect of the present invention comprises an n-channel MIS transistor and a p-channel MIS transistor. The n-channel MIS transistor includes a first source region formed in a semiconductor region on a substrate, a first drain region formed in the semiconductor region apart from the first source region, a first gate insulating film formed on the semiconductor region between the first source region and the first drain region, and a first gate electrode formed on the first gate insulating film. The p-channel MIS transistor includes a second source region formed in the semiconductor region, a second drain region formed in the semiconductor region apart from the second source region, a second gate insulating film formed on the semiconductor region between the second source region and the second drain region, and a second gate electrode formed on the second gate insulating film. The first drain region and the second drain region are arranged to be connected to each other and made of the same material, and at least one of the first source region and the second source region is made of a material different from the first drain region and the second drain region.

### BRIEF DESCRIPTION OF THE SEVERAL VIEWS OF THE DRAWING

FIG. 1 is a view showing the layout of nMOS transistors and pMOS transistors of a CMOS in an SRAM cell of a first embodiment of the present invention;

FIG. 2A is a sectional view taken along a line 2A-2A in the SRAM cell shown in FIG. 1;

FIG. 2B is a sectional view showing the first step of a method of fabricating the nMOS transistor and pMOS transistor of the first embodiment;

FIG. 3A is a sectional view showing the second step of the method of fabricating the nMOS transistor and pMOS transistor of the first embodiment;

FIG. 3B is a sectional view showing the third step of the method of fabricating the nMOS transistor and pMOS transistor of the first embodiment;

FIG. 4A is a sectional view showing the fourth step of the method of fabricating the nMOS transistor and pMOS transistor of the first embodiment;

FIG. 4B is a sectional view showing the fifth step of the method of fabricating the nMOS transistor and pMOS transistor of the first embodiment;

FIG. 5 is a view showing the layout of nMOS transistors and pMOS transistors of a CMOS in an SRAM cell of a second embodiment of the present invention;

FIG. 6A is a sectional view taken along a line 6A-6A in the SRAM cell shown in FIG. 5;

FIG. 6B is a sectional view showing the first step of a method of fabricating the nMOS transistor and pMOS transistor of the second embodiment;

FIG. 7A is a sectional view showing the second step of the method of fabricating the nMOS transistor and pMOS transistor of the second embodiment;

FIG. 7B is a sectional view showing the third step of the method of fabricating the nMOS transistor and pMOS transistor of the second embodiment;

FIG. 8A is a sectional view showing the fourth step of the method of fabricating the nMOS transistor and pMOS transistor of the second embodiment;

FIG. 8B is a sectional view showing the fifth step of the method of fabricating the nMOS transistor and pMOS transistor of the second embodiment;

FIG. 9 is a view showing the layout of nMOS transistors and pMOS transistors of a CMOS in an SRAM cell of a third embodiment of the present invention;

FIG. 10 is a view showing the layout of nMOS transistors and pMOS transistors of a CMOS in an SRAM cell of a fourth embodiment of the present invention; and

FIG. 11 is a view showing the layout of nMOS transistors and pMOS transistors of a CMOS in an SRAM cell of a fifth embodiment of the present invention.

### DETAILED DESCRIPTION OF THE INVENTION

Embodiments of the present invention will be explained below with reference to the accompanying drawing. The following embodiments will take a MOS transistor as an example of a MIS transistor. In the following explanation, the same reference numerals denote the same parts throughout the drawing.

### First Embodiment

A semiconductor device of the first embodiment of the present invention will be explained below.

FIG. 1 is a view showing the layout of nMOS transistors and pMOS transistors of a CMOS in an SRAM cell of the first embodiment. This SRAM cell has nMOS transistors TR as switching transistors (transfer transistors), pMOS transistors LO as load transistors, and nMOS transistors DR as drive transistors. Drain regions 17A of the nMOS transistors TR and DR and drain regions 17B of the pMOS transistors LO are made of the same material, i.e., silicon (Si). Source regions 18A of the nMOS transistors TR and DR are made of silicon carbide (SiC), and source regions 18B of the pMOS transistors LO are made of silicon germanium (SiGe). A gate electrode G1 shown in FIG. 1 is a common gate of the pMOS transistor LO and nMOS transistor DR. This common gate is electrically connected to a common drain region of the other pair of the pMOS transistor LO and nMOS transistor DR via a contact CP. A gate electrode G2 is the gate of the nMOS transistor TR. The source region 18A of the nMOS transistor TR is connected to a bit line (not shown).

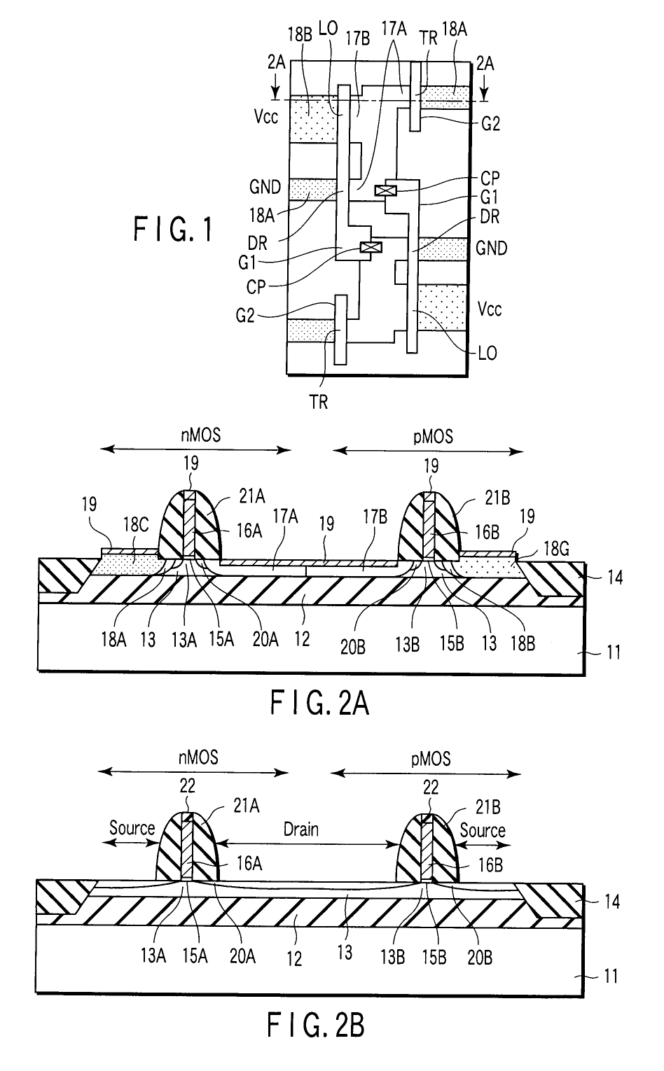

FIG. 2A is a sectional view taken along a line 2A-2A in the SRAM cell shown in FIG. 1, and shows the sections of the nMOS transistor TR and pMOS transistor LO.

A box film 12 as a buried insulating layer is formed on a p-type silicon substrate or n-type silicon substrate 11, and semiconductor regions 13 are formed on the box film 12. The box film 12 is made of, e.g., a silicon oxide film (SiO₂), and the semiconductor regions 13 are made of, e.g., silicon. An element isolation insulating film 14 is buried in the box film 12 and semiconductor regions 13. The semiconductor regions 13 as active element portions are arranged on the box film 12 surrounded by the element isolation insulating film 14.

The nMOS transistor and pMOS transistor are formed in the active element portions. The structures of the nMOS transistor and pMOS transistor will be explained below.

First, the structure of the nMOS transistor will be explained. A gate insulating film 15A is formed on a channel region 13A of the semiconductor region 13, and a gate electrode 16A is formed on the gate insulating film 15A. The drain region 17A and source region 18A are formed to sandwich the channel region 13A below the gate insulating film 15A. The drain region 17A is formed in the semiconductor region 13 made of silicon. The source region 18A is formed in a silicon carbide (SiC) layer 18C formed on the box film 12. Note that as shown in FIG. 2A, the source region 18A made of a high impurity concentration diffusion layer is not only formed in the SiC layer 18C but also extends into the silicon semiconductor region 13 beyond the boundary between the SiC layer 18C and silicon. Silicide films 19 are formed on the source region 18A, drain region 17A, and gate electrode 16A. In addition, shallow diffusion layers 20A are formed inside the source region 18A and drain region 17A, and sidewall insulating films 21A are formed on the sidewalls of the gate electrode 16A.

Next, the structure of the pMOS transistor will be explained. A gate insulating film 15B is formed on a channel region 13B of the semiconductor region 13, and a gate electrode 16B is formed on the gate insulating film 15B. The drain region 17B and source region 18B are formed to sandwich the channel region 13B below the gate insulating film 15B. The drain region 17B is formed in the semiconductor region 13 made of silicon. The source region 18B is formed in a silicon germanium (SiGe) layer 18G formed on the box film 12. Note that as shown in FIG. 2A, the source region 18B made of a high impurity concentration diffusion layer is not only formed in the SiGe layer 18G but also extends into the silicon semiconductor region 13 beyond the boundary between the SiGe layer 18G and silicon. Silicide films 19 are formed on the source region 18B, drain region 17B, and gate electrode 16B. In addition, shallow diffusion layers 20B are formed inside the source region 18B and drain region 17B, and sidewall insulating films 21B are formed on the sidewalls of the gate electrode 16B.

In the nMOS transistor and pMOS transistor having the above structures, the source regions 18A and 18B apply tensile stress and compressive stress to the channel regions 13A and 13B, thereby improving the transistor characteristics. Also, the drain region 17A of the nMOS transistor and the drain region 17B of the pMOS transistor are made of the same material (in this embodiment, silicon). Therefore, a crystal defect and the like do not occur in a region where the drain regions 17A and 17B are connected. This makes it possible to prevent deterioration of the transistor characteristics of the nMOS transistor and pMOS transistor caused by a crystal defect and the like.

In addition, when the drain regions of the nMOS transistor and PMOS transistor are made of SiC and SiGe, i.e., the same materials as the source regions of these transistors and a silicide film is formed on the drain regions, the formation of the silicide film does not evenly progress due to the difference between the silicidation rates of the materials (SiC and SiGe) forming the drain regions, and a problem such as the division of the silicide film in the junction region arises. This is so because if there is a difference between the silicidation rates, a metal film deposited in a region where the silicidation rate is low (the phase transition temperature is high) flows into a region where the silicidation rate is high (the phase transition temperature is low), thereby forming a region where the silicide film is thinned or divided in particularly the boundary portion.

By contrast, in the first embodiment as described above, the drain regions 17A and 17B are made of the same material, i.e., silicon. When forming a continuous silicide film on the drain regions 17A and 17B, therefore, it is possible to prevent inconveniences such as the formation of a region where the silicide film is thinned or divided. Note that the nMOS transistor and PMOS transistor having the above structures are formed on a fully depleted SOI (FD-SOI) in this embodiment, but they may also be formed on a partially depleted SOI (PD-SOI) or on a bulk silicon substrate.

A method of fabricating the nMOS transistor and pMOS transistor in the SRAM of the first embodiment will be explained below.

FIGS. 2B, 3A, 3B, 4A, and 4B are sectional views showing the fabrication steps of the nMOS transistor and pMOS transistor of the first embodiment. The following steps illustrate a process using a fully depleted SOI.

First, an SOI wafer (substrate) in which a box film 12 is formed on a p-type silicon substrate or n-type silicon substrate 11 and a semiconductor region 13 made of silicon is formed on the box film 12 is prepared. An element isolation insulating film 14 having a depth of 2,000 Å to 3,500 Å is formed in the box film 12 and semiconductor region 13 of this SOI wafer by the buried element isolation method.

An oxide film (not shown) having a thickness of 200 Å or less is formed on the silicon surface of the semiconductor region (active element portion) 13 surrounded by the element isolation insulating film 14. After that, ion implantation and activation rapid thermal annealing (to be referred to as activation RTA hereinafter) for channel region formation are performed. Typical conditions of ion implantation to the channel region are as follows. For the nMOS transistor, boron (B) is ion-implanted at an acceleration voltage of 10 keV with a dose of 1.5×10¹³ cm⁻². For the pMOS transistor, arsenic (As) is ion-implanted at an acceleration voltage of 80 keV with a dose of 1.0×10¹³ cm⁻².

After that, gate insulating films 15A and 15B having a film thickness of 5 Å to 60 Å are formed on the channel region by thermal oxidation or low-pressure CVD (LPCVD). Subsequently, one of a polysilicon film and a polysilicon germanium each having a film thickness of 500 Å to 2,000 Å is deposited on the gate insulating films 15A and 15B. This film is processed as gate electrodes 16A and 16B later. In addition, a silicon nitride film 22 is formed on the polysilicon film or polysilicon germanium film. Resist patterning for gate electrode formation is then performed by photolithography, X-ray lithography, or electron beam lithography. Subsequently, the resist pattern is used as a mask film to etch the silicon nitride film 22 and polysilicon film (or polysilicon germanium film) by reactive ion etching (RIE), thereby forming gate electrodes 16A and 16B. As a gate insulating film, it is possible to use, e.g., a silicon oxide film (SiO₂), SiON, SiN, or HfSiON as a high-k film.

Then, post-oxidation SiO₂ (not shown) 10 Å to 60 Å thick is formed by thermal oxidation as post oxidation, and shallow diffusion layers 20A and 20B are formed. Examples of the ion implantation conditions are as follows. For the n-type shallow diffusion layer 20A, As is ion-implanted at an acceleration voltage of 1 keV to 5 keV with a dose of 5.0×10¹⁴ cm⁻² to 1.5×10¹⁵ cm⁻². For the p-type shallow diffusion layer 20B, BF₂ is ion-implanted at an acceleration voltage of 1 keV to 3 keV with a dose of 5.0×10¹⁴ cm⁻² to 1.5×10¹⁵ cm⁻², or B (boron) is ion-implanted at an acceleration voltage of 1 keV or less with a dose of 5.0×10¹⁴ cm⁻² to 1.5×10¹⁵ cm⁻². Subsequently, activation RTA is performed. After that, sidewall insulating films 21A and 21B are formed on the sidewalls of the gate electrodes 16A and 16B (FIG. 2B).

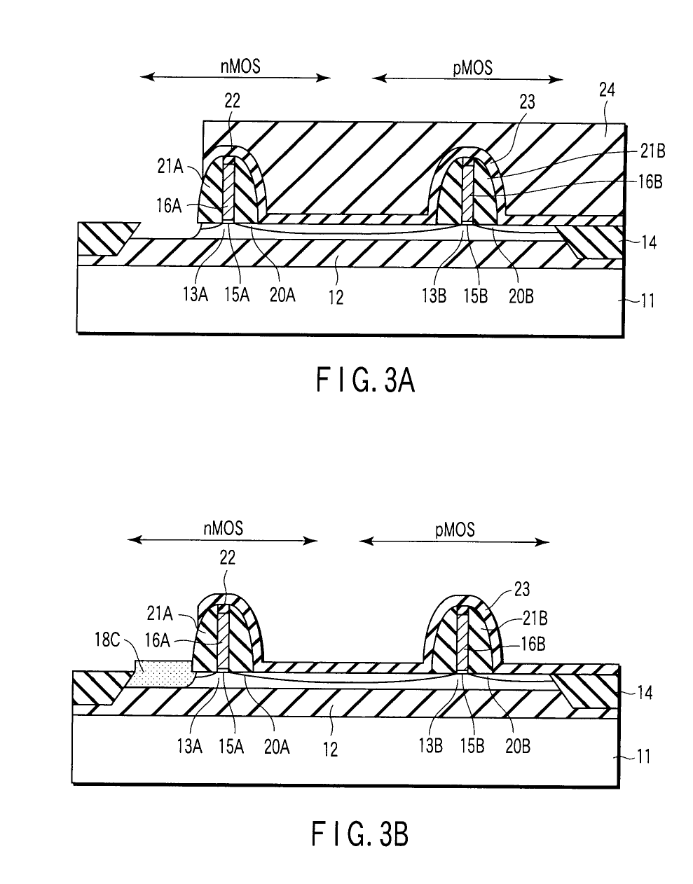

Then, as shown in FIG. 3A, a silicon oxide film or a nitrogen-containing silicon oxide film 23 whose etching rate to hydrofluoric acid is lower than that of a silicon oxide film is formed and patterned by using a resist film 24 as a mask film, so as to cover the pMOS region and a drain formation region and the gate electrode 16A in the nMOS region. Silicon in a source formation region of the nMOS transistor is etched by RIE or CDE (Chemical Dry Etching). This etching can be performed with the resist film 24 being attached or after removing it (FIG. 3A).

Next, the resist film 24 is removed, and an SiC layer 18C is buried in the source formation region of the nMOS transistor. More specifically, the SiC layer 18C is buried by epitaxial selective growth from a channel region (silicon) 13A. Since the SiC layer 18C is buried in the source formation region of the nMOS transistor, tensile stress can be applied to the channel region 13A of the nMOS transistor (FIG. 3B). Note that if epitaxial selective growth in the lateral direction from the channel region 13A is difficult, it is also possible to perform etching such that the silicon portion of the fully depleted SOI partially remains, i.e., to leave silicon on the box film 12 in the source formation region, or to use a partially depleted SOI or bulk silicon instead of the fully depleted SOI. This similarly applies to epitaxial growth of SiGe (to be described later).

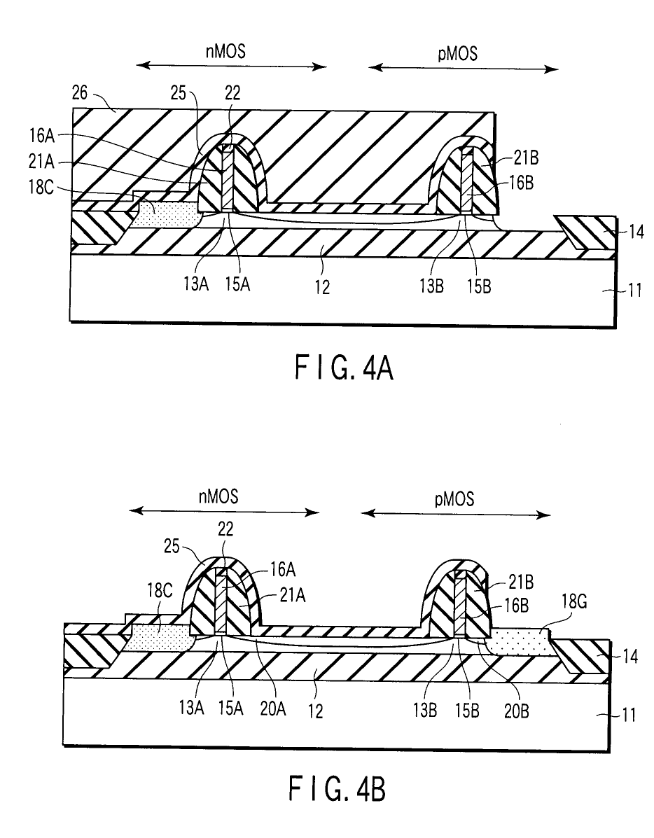

Then, a silicon oxide film 25 and resist film 26 are formed using a process similar to the process used to bury the SiC layer 18C, and silicon in the source formation region of the pMOS transistor is etched away (FIG. 4A). Subsequently, the resist film 26 is removed, and an SiGe layer 18G is buried in the source formation region of the pMOS transistor. More specifically, the SiGe layer 18G is buried by epitaxial selective growth from a channel region (silicon) 13B. Since the SiGe layer 18G is buried in the source formation region of the pMOS transistor, compressive stress can be applied to the channel region 13B of the pMOS transistor (FIG. 4B).

After the pMOS region is protected by photolithography, ion implantation is performed to form a high impurity concentration diffusion layer in the nMOS region. In addition, after the nMOS region is protected by photolithography, ion implantation is performed to form a high impurity concentration diffusion layer in the pMOS region. Subsequently, activation RTA is performed to form a source region 18A in the SiC layer 18C and a drain region 17A in the silicon 13 in the nMOS region, and form a source region 18B in the SiGe layer 18G and a drain region 17B in the silicon 13 in the pMOS region.

Then, the oxide films on the silicon 13 and the like and the silicon nitride films 22 on the gate electrodes 16A and 16B are removed. If necessary, the sidewall insulating films 21A and 21B are also removed, and sidewall insulating films are formed on the gate sidewalls again. Subsequently, silicide films 19 are formed on the drain regions 17A and 17B, source regions 18A and 18B, and gate electrodes 16A and 16B (FIG. 2A). In this case, no defect occurs on the silicide film 19 because the drain region 17A of the nMOS transistor and the drain region 17B of the PMOS transistor are made of the same material, i.e., silicon. That is, it is possible to prevent the silicide film 19 formed on the drain regions 17A and 17B from being partially thinned or divided. As this silicide film, it is possible to use, e.g., a nickel silicide film. A nickel silicide film formation process is as follows. After nickel is deposited by sputtering, RTA for silicidation is performed. More specifically, after nickel silicide is formed by performing RTA at 400° C. to 500° C., unreacted nickel is etched away by a solution mixture of sulfuric acid and a hydrogen peroxide solution, thereby leaving the nickel silicide film. In this manner, the salicide process is complete.

Note that it is also possible to deposit a TiN film after nickel is sputtered, or to perform etching by using a solution mixture of sulfuric acid and a hydrogen peroxide solution after low-temperature RTA is performed at 250° C. to 400° C., and then perform RTA again at 400° C. to 500° C. in order to decrease the sheet resistance (two-step annealing). Note also that a silicide species such as Co, Er, Pt, Pd, or Yb may also be used instead of nickel silicide.

After that, a CMOS device is fabricated as follows. After the sectional structure shown in FIG. 2A is formed, a film having RIE selectivity higher than that of an interlayer film material is formed on the silicide films 19. Subsequently, TEOS, BPSG, SiN, or the like is deposited as an interlayer film on this film, and the interlayer film is planarized by CMP. The film having RIE selectivity higher than that of the interlayer film material is formed to prevent deterioration of the junction leakage caused by etching of the silicide film when RIE is performed to form a contact hole in the interlayer film after the interlayer film is formed on the structure shown in FIG. 2A. After that, an exposure step of forming a contact hole is performed, and a contact hole is formed by performing RIE with a resist mask. Subsequently, Ti or TiN is deposited as a barrier metal in the contact hole, and W is selectively grown or formed into a blanket. After that, CMP is performed. Finally, a metal for forming interconnections is deposited, and an exposure step of forming interconnections is performed. In this way, a CMOS device is formed.

### Second Embodiment

A semiconductor device of the second embodiment of the present invention will be explained below. The same reference numerals as in the first embodiment denote the same parts, and a repetitive explanation will be omitted.

FIG. 5 is a view showing the layout of nMOS transistors and pMOS transistors of a CMOS in an SRAM cell of the second embodiment. This SRAM cell has nMOS transistors TR as switching transistors (transfer transistors), pMOS transistors LO as load transistors, and nMOS transistors DR as drive transistors. Drain regions 31A of the nMOS transistors TR and DR and drain regions 31B of the pMOS transistors LO are made of the same material, i.e., silicon carbide (SiC). Source regions 18A of the nMOS transistors TR and DR are also made of silicon carbide (SiC), and source regions 18B of the pMOS transistors LO are made of silicon germanium (SiGe).

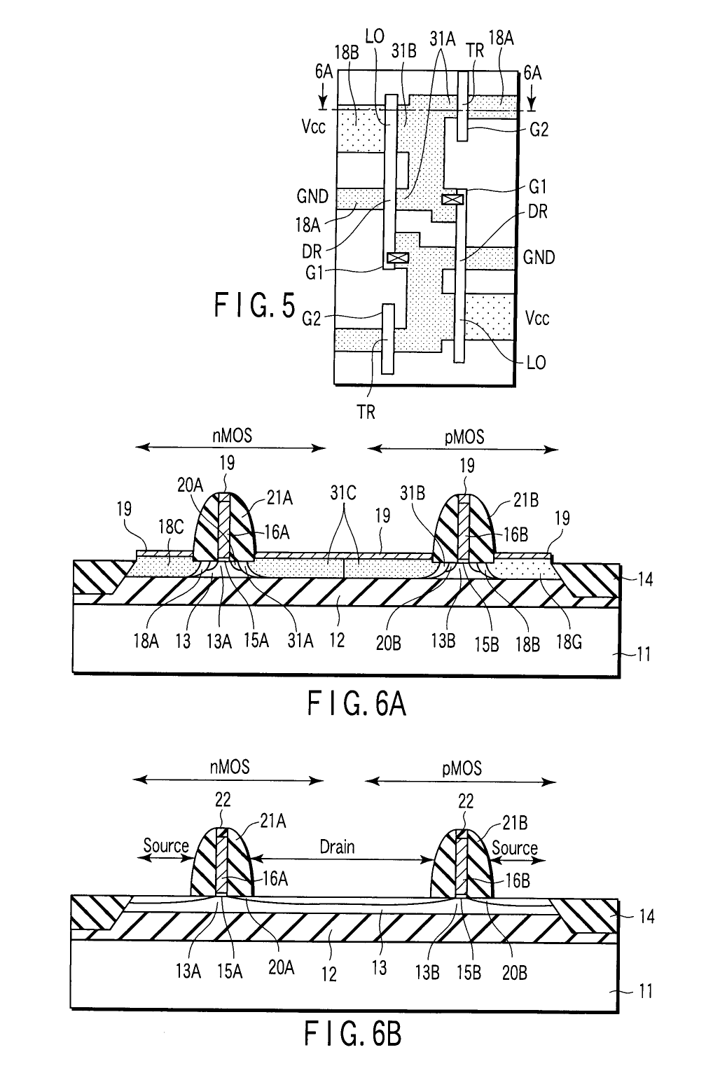

FIG. 6A is a sectional view taken along a line 6A-6A in the SRAM cell shown in FIG. 5, and shows the sections of the nMOS transistor TR and pMOS transistor LO.

The nMOS transistor and pMOS transistor are formed in active element portions on a box film 12 surrounded by an element isolation insulating film 14. The structures of the nMOS transistor and pMOS transistor will be explained below.

First, the structure of the nMOS transistor will be explained. A gate insulating film 15A is formed on a channel region 13A of a semiconductor region 13, and a gate electrode 16A is formed on the gate insulating film 15A. The drain region 31A and source region 18A are formed to sandwich the channel region 13A below the gate insulating film 15A. The drain region 31A is formed in a silicon carbide (SiC) layer 31C formed on the box film 12. The source region 18A is also formed in a silicon carbide layer 18C formed on the box film 12. Note that as shown in FIG. 6A, the drain region 31A and source region 18A made of high impurity concentration diffusion layers are not only formed in the SiC layers 31C and 18C but also extend into the silicon semiconductor region 13 beyond the boundary between the SiC layer 31C and silicon and the boundary between the SiC layer 18C and silicon. Silicide films 19 are formed on the source region 18A, drain region 31A, and gate electrode 16A. In addition, shallow diffusion layers 20A are formed inside the source region 18A and drain region 31A, and sidewall insulating films 21A are formed on the sidewalls of the gate electrode 16A.

Next, the structure of the pMOS transistor will be explained. A gate insulating film 15B is formed on a channel region 13B of a semiconductor region 13, and a gate electrode 16B is formed on the gate insulating film 15B. The drain region 31B and source region 18B are formed to sandwich the channel region 13B below the gate insulating film 15B. The drain region 31B is formed in a silicon carbide layer 31C formed on the box film 12. The source region 18B is formed in a silicon germanium (SiGe) layer 18G formed on the box film 12. Note that as shown in FIG. 6A, the drain region 31B and source region 18B made of high impurity concentration diffusion layers are not only formed in the SiC layer 31C and SiGe layer 18G but also extend into the silicon semiconductor region 13 beyond the boundary between the SiC layer 31C and silicon and the boundary between the SiGe layer 18G and silicon. Silicide films 19 are formed on the source region 18B, drain region 31B, and gate electrode 16B. In addition, shallow diffusion layers 20B are formed inside the source region 18B and drain region 31B, and sidewall insulating films 21B are formed on the sidewalls of the gate electrode 16B.

In the nMOS transistor and pMOS transistor having the above structures, the drain region 31A of the nMOS transistor and the drain region 31B of the pMOS transistor are made of the same material (in this embodiment, silicon carbide). Therefore, although the drain region 31B applies strain that cancels compressive stress to the channel region 13B in the pMOS transistor, both the drain region 31A and source region 18A can apply large tensile stress to the channel region 13A in the nMOS transistor. This makes it possible to significantly improve the characteristics of the nMOS transistor (particularly drive transistor), which are particularly important in an SRAM cell. Also, as in the first embodiment, a crystal defect and the like do not occur in a region where the drain regions 31A and 31B are connected. This makes it possible to prevent deterioration of the transistor characteristics of the nMOS transistor and pMOS transistor caused by a crystal defect and the like. In addition, when forming a continuous silicide film on the drain regions 31A and 31B, it is possible to prevent inconveniences such as the formation of a region where the silicide film is thinned or divided, since the drain regions 31A and 31B are made of the same material, i.e., silicon carbide as described above. Note that the nMOS transistor and pMOS transistor having the above structures are formed on a fully depleted SOI (FD-SOI) in this embodiment, but they may also be formed on a partially depleted SOI (PD-SOI) or on a bulk silicon substrate.

A method of fabricating the nMOS transistor and pMOS transistor in the SRAM of the second embodiment will be explained below.

FIGS. 6B, 7A, 7B, 8A, and 8B are sectional views showing the fabrication steps of the nMOS transistor and pMOS transistor of the second embodiment. The following steps illustrate a process using a fully depleted SOI.

As shown in FIG. 6B, the process is the same as the first embodiment until the step of forming sidewall insulating films 21A and 21B on the sidewalls of gate electrodes 16A and 16B.

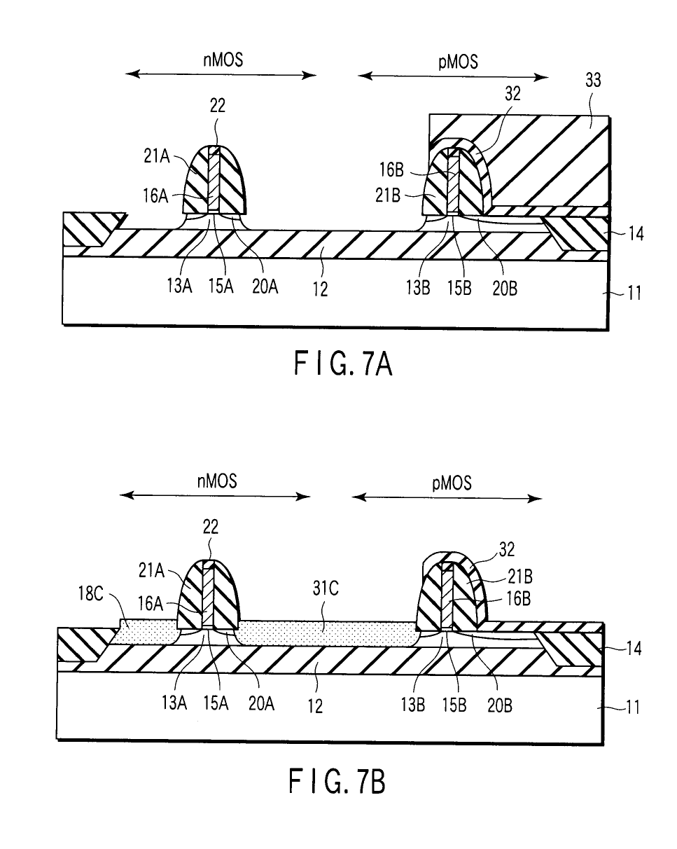

Then, as shown in FIG. 7A, a silicon oxide film or a nitrogen-containing silicon oxide film 32 whose etching rate to hydrofluoric acid is lower than that of a silicon oxide film is formed and patterned by using a resist film 33 as a mask film, so as to cover a source formation region and the gate electrode 16B in the pMOS region. Silicon in a source formation region and drain formation region of the nMOS transistor and a drain formation region in the pMOS region is etched by RIE or CDE (Chemical Dry Etching). This etching can be performed with the resist film 33 being attached or after removing it (FIG. 7A).

Next, the resist film 33 is removed, and SiC layers 18C and 31C are buried in the source/drain formation regions of the nMOS transistor and the drain formation region of the pMOS transistor. More specifically, the SiC layers 18C and 31C are buried by epitaxial selective growth from channel regions (silicon) 13A and 13B. Since the SiC layers 18C and 31C are buried in the source formation region and drain formation region of the nMOS transistor, tensile stress can be applied to the channel region 13A of the nMOS transistor (FIG. 7B). Note that if epitaxial selective growth in the lateral direction from the channel regions 13A and 13B is difficult, it is also possible to perform etching such that the silicon portion of the fully depleted SOI partially remains, i.e., to leave silicon on a box film 12 in the source/drain formation regions, or to use a partially depleted SOI or bulk silicon instead of the fully depleted SOI. This similarly applies to epitaxial growth of SiGe (to be described later).

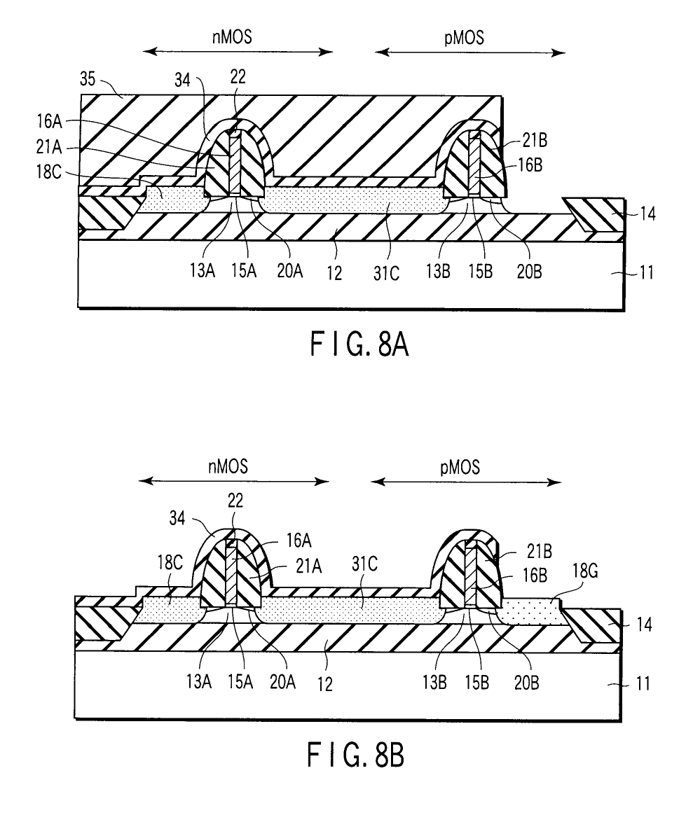

Then, a silicon oxide film 34 and resist film 35 are formed using a process similar to the process used to bury the SiC layers 18C and 31C, and silicon in the source formation region of the pMOS transistor is etched away (FIG. 8A). Subsequently, the resist film 35 is removed, and an SiGe layer 18G is buried in the source formation region of the pMOS transistor. More specifically, the SiGe layer 18G is buried by epitaxial selective growth from the channel region (silicon) 13B. Since the SiGe layer 18G is buried in the source formation region of the pMOS transistor, compressive stress can be applied to the channel region 13B of the pMOS transistor (FIG. 8B).

After the pMOS region is protected by photolithography, ion implantation is performed to form a high impurity concentration diffusion layer in the nMOS region. In addition, after the nMOS region is protected by photolithography, ion implantation is performed to form a high impurity concentration diffusion layer in the pMOS region. Subsequently, activation RTA is performed to form a source region 18A in the SiC layer 18C and a drain region 31A in the SiC layer 31C in the nMOS region, and form a source region 18B in the SiGe layer 18G and a drain region 31B in the SiC layer 31C in the pMOS region.

Then, the oxide films on the SiC layers 18C and 31C and the like and silicon nitride films 22 on the gate electrodes 16A and 16B are removed. If necessary, the sidewall insulating films 21A and 21B are also removed, and sidewall insulating films are formed on the gate sidewalls again. Subsequently, silicide films 19 are formed on the drain regions 31A and 31B, source regions 18A and 18B, and gate electrodes 16A and 16B (FIG. 6A). In this case, no defect occurs on the silicide film 19 because the drain region 31A of the nMOS transistor and the drain region 31B of the pMOS transistor are made of the same material, i.e., silicon carbide. That is, it is possible to prevent the silicide film 19 formed on the drain regions 31A and 31B from being partially thinned or divided. As this silicide film, it is possible to use, e.g., a nickel silicide film. A nickel silicide film formation process is the same as in the first embodiment. It is also possible to use a silicide species such as Co, Er, Pt, Pd, or Yb instead of nickel silicide, as in the first embodiment.

### Third Embodiment

A semiconductor device of the third embodiment of the present invention will be explained below. The same reference numerals as in the first embodiment denote the same parts, and a repetitive explanation will be omitted.

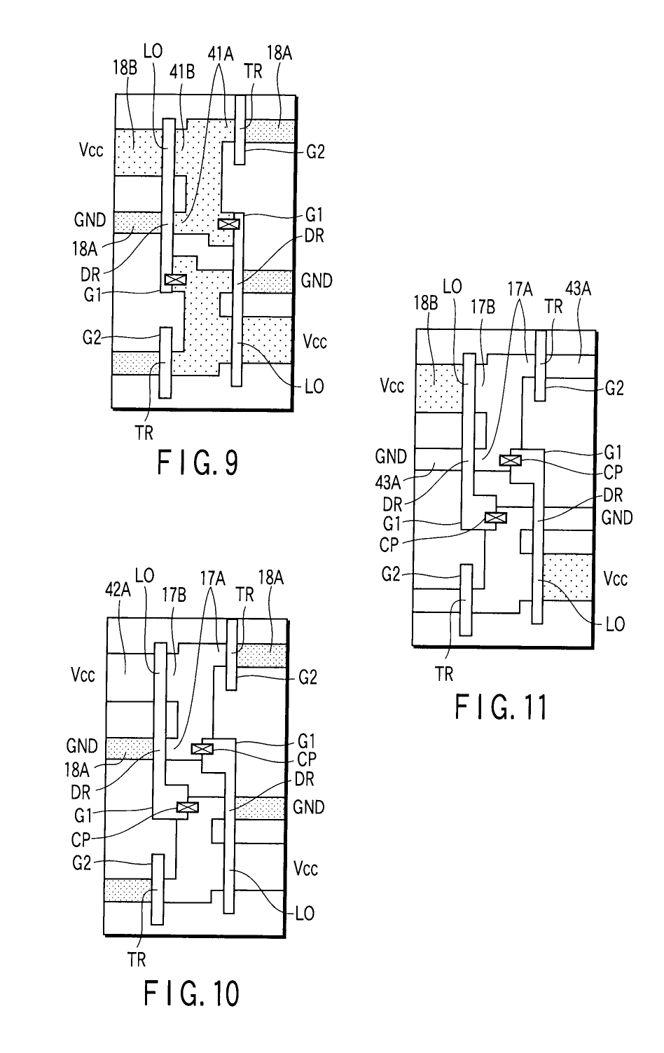

FIG. 9 is a view showing the layout of nMOS transistors and pMOS transistors of a CMOS in an SRAM cell of the third embodiment. This SRAM cell has nMOS transistors TR as switching transistors (transfer transistors), pMOS transistors LO as load transistors, and nMOS transistors DR as drive transistors. Drain regions 41A of the nMOS transistors TR and DR and drain regions 41B of the pMOS transistors LO are made of the same material, i.e., silicon germanium (SiGe). Source regions 18A of the nMOS transistors TR and DR are made of silicon carbide (SiC), and source regions 18B of the pMOS transistors LO are made of silicon germanium.

The fabrication steps are the same as in the first embodiment except that an SiC layer is buried by etching only a source formation region of the nMOS transistor in FIG. 3A, and that an SiGe layer is buried by etching a drain formation region of the nMOS transistor and a drain formation region and source formation region of the pMOS transistor in FIG. 4A.

In the nMOS transistor and pMOS transistor having the structures as described above, the drain region 41A of the nMOS transistor and the drain region 41B of the pMOS transistor are made of the same material (in this embodiment, silicon germanium). Therefore, a crystal defect and the like do not occur in a region where the drain regions 41A and 41B are connected. This makes it possible to prevent deterioration of the transistor characteristics of the nMOS transistor and pMOS transistor caused by a crystal defect and the like. In addition, when forming a continuous silicide film on the drain regions 41A and 41B, it is possible to prevent inconveniences such as the formation of a region where the silicide film is thinned or divided, since the drain regions 41A and 41B are made of the same material, i.e., silicon germanium as described above. Note that the transistors can be formed not only on a fully depleted SOT (FD-SOI) but also on a partially depleted SOT (PD-SOI) or on a bulk silicon substrate in the third embodiment as well.

### Fourth Embodiment

A semiconductor device of the fourth embodiment of the present invention will be explained below. The same reference numerals as in the first embodiment denote the same parts, and a repetitive explanation will be omitted.

FIG. 10 is a view showing the layout of nMOS transistors and pMOS transistors of a CMOS in an SRAM cell of the fourth embodiment. This SRAM cell has nMOS transistors TR as switching transistors (transfer transistors), pMOS transistors LO as load transistors, and nMOS transistors DR as drive transistors. Drain regions 17A of the nMOS transistors TR and DR and drain regions 17B of the pMOS transistors LO are made of the same material, i.e., silicon (Si). Source regions 18A of the nMOS transistors TR and DR are made of silicon carbide (SiC), and source regions 42A of the pMOS transistors LO are made of silicon.

The fabrication steps are the same as in the first embodiment except that an SiC layer is buried by etching only a source formation region of the nMOS transistor in FIG. 3A, without etching other source formation regions and drain formation regions.

In the nMOS transistor and pMOS transistor having the structures as described above, the drain region 17A of the nMOS transistor and the drain region 17B of the pMOS transistor are made of the same material (in this embodiment, silicon). Therefore, a crystal defect and the like do not occur in a region where the drain regions 17A and 17B are connected. This makes it possible to prevent deterioration of the transistor characteristics of the nMOS transistor and pMOS transistor caused by a crystal defect and the like. In addition, when forming a continuous silicide film on the drain regions 17A and 17B, it is possible to prevent inconveniences such as the formation of a region where the silicide film is thinned or divided, since the drain regions 17A and 17B are made of the same material, i.e., silicon as described above. Note that the transistors can be formed not only on a fully depleted SOI (FD-SOI) but also on a partially depleted SOI (PD-SOI) or on a bulk silicon substrate in the fourth embodiment as well.

### Fifth Embodiment

A semiconductor device of the fifth embodiment of the present invention will be explained below. The same reference numerals as in the first embodiment denote the same parts, and a repetitive explanation will be omitted.

FIG. 11 is a view showing the layout of nMOS transistors and pMOS transistors of a CMOS in an SRAM cell of the fifth embodiment. This SRAM cell has nMOS transistors TR as switching transistors (transfer transistors), pMOS transistors LO as load transistors, and nMOS transistors DR as drive transistors. Drain regions 17A of the nMOS transistors TR and DR and drain regions 17B of the pMOS transistors LO are made of the same material, i.e., silicon (Si). Source regions 43A of the nMOS transistors TR and DR are also made of silicon, and source regions 18B of the pMOS transistors LO are made of silicon germanium.

The fabrication steps are the same as in the first embodiment except that an SiGe layer is buried by etching only a source formation region of the pMOS transistor in FIG. 4A, without etching other source formation regions and drain formation regions.

In the nMOS transistor and pMOS transistor having the structures as described above, the drain region 17A of the nMOS transistor and the drain region 17B of the pMOS transistor are made of the same material (in this embodiment, silicon). Therefore, a crystal defect and the like do not occur in a region where the drain regions 17A and 17B are connected. This makes it possible to prevent deterioration of the transistor characteristics of the nMOS transistor and pMOS transistor caused by a crystal defect and the like. In addition, when forming a continuous silicide film on the drain regions 17A and 17B, it is possible to prevent inconveniences such as the formation of a region where the silicide film is thinned or divided, since the drain regions 17A and 17B are made of the same material, i.e., silicon as described above. Note that the transistors can be formed not only on a fully depleted SOI (FD-SOI) but also on a partially depleted SOI (PD-SOI) or on a bulk silicon substrate in the fifth embodiment as well.

In the embodiments of the present invention as explained above, if there is a region where the drain regions of an nMOS transistor and pMOS transistor are connected, these drain regions connected to each other are made of the same material (e.g., Si, SiGe, or SiC), thereby preventing the occurrence of defects such as a crystal defect in this region where the drain regions are connected, and further preventing the occurrence of defects in a silicide film formed on these drain regions. Also, when the process of each embodiment of the present invention is applied to, e.g., bulk silicon, the junction leakage can be reduced because silicide film formation defects are improved.

Note that in the embodiments of the present invention, no strain is applied from both the drain region and source region to at least one of the nMOS transistor and pMOS transistor, and this makes it difficult to apply large strain to both the nMOS transistor and pMOS transistor. However, the embodiments of the present invention is still applicable to a circuit requiring no large improvement in transistor characteristics, e.g., a circuit that satisfies requirements even by improving the transistor characteristics by applying strain from one of the drain region and source region, or a circuit that satisfies requirements even if the transistor characteristics of one of an nMOS transistor or pMOS transistor can be improved. It is also possible to bury a material different from silicon in only the source region by taking a heterojunction structure or the like into consideration. The embodiments of the present invention can also be applied to this process.

Note that the embodiments of the present invention have been explained by taking a CMOS device in an SRAM as an example, but the embodiments of the present invention are not limited to this example. That is, the embodiments of the present invention are also applicable to a CMOS device in a device having a structure in which the drains (or sources) of an nMOS transistor and pMOS transistor are connected, e.g., an inverter or a logic circuit such as a NAND circuit.

The embodiments of the present invention can provide a semiconductor device including a CMOS device in which any inconveniences that worsen the transistor characteristics do not occur in a drain region where an n-channel MIS transistor and p-channel MIS transistor are connected.

The embodiments described above can be practiced singly, and can also be practiced by appropriately combining them. Furthermore, the above embodiments include inventions in various stages. Accordingly, it is also possible to extract the inventions in the various stages by appropriately combining the constituent elements disclosed in these embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an n-channel MIS transistor including
a first source region formed in a semiconductor region on a substrate,
a first drain region formed in the semiconductor region apart from the first source region,
a first gate insulating film formed on the semiconductor region between the first source region and the first drain region, and
a first gate electrode formed on the first gate insulating film; and
a p-channel MIS transistor including
a second source region formed in the semiconductor region,
a second drain region formed in the semiconductor region apart from the second source region,
a second gate insulating film formed on the semiconductor region between the second source region and the second drain region, and
a second gate electrode formed on the second gate insulating film,
wherein the first drain region and the second drain region are arranged to be connected to each other and made of the same material, and
at least one of the first source region and the second source region is made of a material different from the first drain region and the second drain region.

2. The device according to claim 1, further comprising an insulating layer formed below the semiconductor region.

3. The device according to claim 1, further comprising a silicide film formed on the first source region, the second source region, the first drain region, and the second drain region.

4. The device according to claim 1, wherein the n-channel MIS transistor corresponds to one of a transfer transistor and a drive transistor in a SRAM cell, and the p-channel MIS transistor corresponds to a load transistor in the SRAM cell.

5. A device according to claim 1, wherein the first drain region and the second drain region are made of silicon, the first source region is made of silicon carbide, and the second source region is made of silicon germanium.

6. A device according to claim 5, further comprising an insulating layer formed below the semiconductor region.

7. A device according to claim 5, further comprising a silicide film formed on the first source region, the second source region, the first drain region, and the second drain region.

8. A device according to claim 1, wherein the first drain region, the second drain region, and the first source region are made of silicon carbide, and the second source region is made of silicon germanium.

9. A device according to claim 8, further comprising an insulating layer formed below the semiconductor region.

10. A device according to claim 8, further comprising a silicide film formed on the first source region, the second source region, the first drain region, and the second drain region.

11. The device according to claim 8, wherein the n-channel MIS transistor corresponds to one of a transfer transistor and a drive transistor in a SRAM cell, and the p-channel MIS transistor corresponds to a load transistor in the SRAM cell.

12. A device according to claim 1, wherein the first drain region, the second drain region, and the second source region are made of silicon germanium, and the first source region is made of silicon carbide.

13. A device according to claim 12, further comprising an insulating layer formed below the semiconductor region.

14. A device according to claim 12, further comprising a silicide film formed on the first source region, the second source region, the first drain region, and the second drain region.

15. A device according to claim 1, wherein the first drain region, the second drain region, and the second source region are made of silicon, and the first source region is made of silicon carbide.

16. A device according to claim 15, further comprising an insulating layer formed below the semiconductor region.

17. A device according to claim 15, further comprising a silicide film formed on the first source region, the second source region, the first drain region, and the second drain region.

18. A device according to claim 1, wherein the first drain region, the second drain region, and the first source region are made of silicon, and the second source region is made of silicon germanium.

19. A device according to claim 18, further comprising an insulating layer formed below the semiconductor region.

20. A device according to claim 18, further comprising a silicide film formed on the first source region, the second source region, the first drain region, and the second drain region.
